(19) United States
(12) Patent Application Publication
(10) Pub. No.: US 2023/0335215 A1
(43) Pub. Date: Oct. 19, 2023

(54) DEVICE AND METHOD FOR TESTING FATIGUE CHARACTERISTICS OF SELECTOR

(71) Applicant: INSTITUTE OF MICROELECTRONICS, CHINSE ACADEMY OF SCIENCES, Beijing (CN)

(72) Inventors: Qing LUO, Beijing (CN); Hangbing LV, Beijing (CN); Jie YU, Beijing (CN); Ming LIU, Beijing (CN)

(21) Appl. No.: 18/042,394

(22) PCT Filed: Aug. 24, 2020
(86) PCT No.: PCT/CN2020/110795

§ 371 Date: Feb. 21, 2023

(51) Int. Cl. G11C 29/54; G11C 13/00

(52) U.S. Cl. CPC G11C 29/54; G11C 13/003

(57) ABSTRACT

The present disclosure discloses a device and a method for testing fatigue characteristics of a selector (210). The device includes: a voltage divider (220) and a counter (103). The voltage divider (220) is connected to a selector (210) to be tested and is configured to divide a voltage for the selector (210) to be tested during a test process. The counter (103) is connected to the selector (210) to be tested and is configured to detect voltage and/or current changes of the selector (210) to be tested.

### CROSS REFERENCE

This application is a Section 371 National Stage Application of International Application No. PCT/CN2020/110795, filed on Aug. 24, 2020, the whole disclosure of which is incorporated herein by reference in its entirety.

### TECHNICAL FIELD

The present disclosure relates to a field of memory technology, and in particular to a device and a method for testing fatigue characteristics of a selector.

### BACKGROUND

According to whether semiconductor memories may retain stored information after power failure, the semiconductor memories may be classified into two types: volatile memories and non-volatile memories. With the popularity of portable electronic apparatuses, non-volatile memories are taking an increasing share in the memory market. At present, the FLASH technology is the mainstream of the non-volatile memory market. However, the FLASH technology is facing a series of bottleneck problems, such as large operating voltage, inability to reduce size, insufficient retention time, and the like. Correspondingly, the Resistive Random Access Memory (RRAM) has become the research focus of new type non-volatile memories due to advantages of low operating voltage, non-destructive reading, fast operation speed, simple structure, easy integration, and the like. However, there is a serious crosstalk problem in the resistive variable memory array. Such crosstalk problem will become more serious with an increase of the number and the size of the array, directly affecting the reliability of the RRAM memory and hinder it from being applied.

In order to solve the crosstalk problem, a 1T1R resistive random access memory integrated with a MOS transistor, a 1D1R resistive random access memory with an external diode, and a 1S1R resistive random access memory connected in series with a selector have been proposed. In the RRAM with the 1T1R structure, an area of a storage unit mainly depends on an area of a transistor, thus advantages of the RRAM, such as the simple structure and the small device area may not be fully utilized. Compared with the RRAM with the 1S1R structure, the RRAM with the 1D1R structure is weak in limiting crosstalk current. Therefore, the RRAM with the 1S1R structure is an ideal structure to solve the crosstalk problem at present.

In practical applications, reading the RRAM each time requires the selector of the RRAM to be turned-on once, thus fatigue characteristics (the number of available turning-on) of the selector determine the practical application. In the prior art, the method for measuring the fatigue characteristics of the selector is to use a pulse generator to perform pulse operation on a device, and then verify whether the device fails by reading an off-state resistance value. A system required by this measurement method includes a pulse generator, a reading circuit and a judgment circuit. A complexity of the system is high, and a test time is long due to the fact that reading and judging are needed each time.

### SUMMARY

In an aspect of the present disclosure, a device for testing fatigue characteristics of a selector is disclosed, including: a voltage divider connected to a selector to be tested, wherein the voltage divider is configured to divide a voltage for the selector to be tested during a test process; and a counter connected to the selector to be tested, wherein the counter is configured to detect voltage and/or current changes of the selector to be tested.

According to the embodiments of the present disclosure, the voltage divider and the selector to be tested are connected in series to form an oscillator, and the oscillator is configured to reflect voltage and/or current changes of the selector to be tested during the test process.

According to the embodiments of the present disclosure, the device further includes an oscillation controller, one end of the oscillation controller is connected to the oscillator to control a length of an oscillation period of the oscillator; and the other end of the oscillation controller is grounded to realize a control path connected in parallel with the oscillator.

According to the embodiments of the present disclosure, the other end of the voltage divider is grounded to realize a test path of the device.

According to the embodiments of the present disclosure, the voltage divider has a resistance value Rf satisfying: Rx_min≤Rf≤Rx_max, wherein Rx_min is a resistance value when a turn-on voltage of the selector to be tested is greater than a threshold voltage of the selector to be tested, and Rx_max is a resistance value when the turn-on voltage of the selector to be tested is less than the threshold voltage of the selector to be tested.

According to the embodiments of the present disclosure, the device further includes: a power supply connected to the oscillator, wherein the power supply is configured to supply power to the oscillator at a constant voltage.

According to the embodiments of the present disclosure, the counter is connected in parallel with the selector to be tested to detect the voltage change of the selector to be tested.

According to the embodiments of the present disclosure, the counter is connected in series with the selector to be tested to detect the current change of the selector to be tested.

In another aspect of the present disclosure, a method for testing fatigue characteristics of a selector applied to the device described above is disclosed, the method comprises: supplying power to an oscillator formed by the selector to be tested and the voltage divider at a constant voltage though a power supply, so as to realize voltage and/or current changes of the selector to be tested during a test process; and realizing at least one oscillation period of the oscillator in response to the constant voltage power supply.

According to the embodiments of the present disclosure, the realizing at least one oscillation period of the oscillator in response to the constant voltage power supply comprises: realizing that a turn-on voltage of the selector to be tested being greater than a threshold voltage of the selector to be tested in response to the constant voltage power supply, so that a current in a test path of the device decreases; and realizing that the turn-on voltage of the selector to be tested being less than the threshold voltage of the selector to be tested in response to the decrease of the current in the test path, so that at least one oscillation period of the oscillator is completed, wherein the voltage divider is connected in series with the selector to be tested to form the oscillator, and the oscillator is configured to reflect voltage and/or current changes of the selector to be tested during the test process.

### BRIEF DESCRIPTION OF THE DRAWINGS

FIG. 1 is a schematic diagram of a logical composition of a device for testing fatigue characteristics of a selector according to the embodiments of the present disclosure.

FIG. 2A is a schematic diagram of a voltage-current relationship of a selector according to the embodiments of the present disclosure.

FIG. 2B is a schematic diagram of a voltage-time relationship before a selector fails according to the embodiments of the present disclosure.

FIG. 2C is a schematic diagram of a voltage-time relationship after a selector fails according to the embodiments of the present disclosure.

FIG. 3A is a schematic diagram of a logical composition of a counter of a device for testing fatigue characteristics of a selector according to the embodiments of the present disclosure.

FIG. 3B is a schematic diagram of a logical composition of another counter of a device for testing fatigue characteristics of a selector according to the embodiments of the present disclosure.

FIG. 4 is a schematic diagram of a logical composition of an oscillation controller in a device for testing fatigue characteristics of a selector according to the embodiments of the present disclosure.

FIG. 5 is a flow diagram of a method for testing fatigue characteristics of a selector according to the embodiments of the present disclosure.

### DETAILED DESCRIPTION OF EMBODIMENTS

In order to make the objectives, technical solutions and advantages of the present disclosure more apparent, the present disclosure will be further described in detail in combination with specific embodiments with reference to the accompanying drawings.

In the prior art, reading a RRAM each time requires a selector of the RRAM to be turned on once, and the on-off times of the selector determines an actual service life of the RRAM device, reflecting fatigue characteristics of the selector of the RRAM device. In the prior art, the fatigue characteristic test of the selector requires a use of a pulse generator to perform a pulse operation on a device. Based on the pulse operation, on-state and off-state resistance values of the selector are read to verify the on-off times of the selector, and to judge whether the selector fails. Therefore, in the prior art, the pulse generator needs to be provided with a reading circuit and a judgment circuit, which requires a high composition complexity of a circuit system, and is easy to cause an over long test time.

In order to solve technical problems of high complexity and long test time in a control system for testing fatigue characteristics of a selector in the prior art, the present disclosure discloses a device and a method for testing fatigue characteristics of a selector.

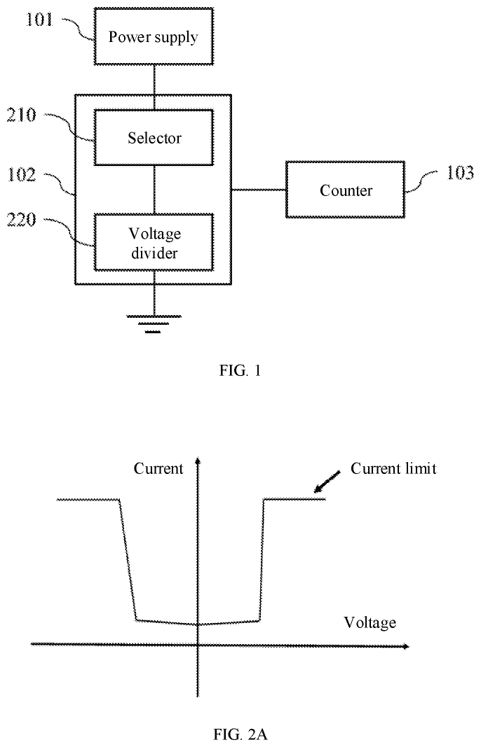

FIG. 1 is a schematic diagram of a logical composition of a device for testing fatigue characteristics of a selector according to the embodiments of the present disclosure.

As shown in FIG. 1, an aspect of the present disclosure discloses a device for testing fatigue characteristics of a selector, wherein a selector 210 is a selector to be tested. The device includes: a voltage divider 220 and a counter. The voltage divider 220 is connected to the selector 210 to be tested, and is used to divide a voltage for the selector 210 during a test process. The counter 103 is connected to the selector 210 to be tested, and is used to detect voltage and/or current changes of the selector 210 to be tested.

According to the embodiments of the present disclosure, the voltage divider 220 is connected in series with the selector 210 to be tested to form an oscillator 102, and the oscillator 102 is used to reflect voltage and/or current changes of the selector 210 during the test process.

As shown in FIG. 1, according to the embodiments of the present disclosure, the counter 103 is used to connect to the oscillator 102, so that the counter 103 may record the number of oscillations of the oscillator 102 to reflect the number of the turning-on of the selector 210 to be tested. The number of the turning-on of the selector 210 may be a test object based on a voltage change of the selector 210 or a current change in a test circuit. For details, see the following description.

It can be seen that, the device of the present disclosure selects the selector 210 to be tested as a composition of the oscillator 102, so that a structure of the device of the present disclosure is more simplified, thereby complex circuit compositions such as a pulse generator, a judgment circuit and the like are omitted. In addition, periodic voltage and/or current oscillations are realized based on the characteristics of the selector 210, which shortens a test period and saves a test time. Moreover, the device is extremely simple in composition and low in cost, thus having an important commercial application value.

As shown in FIG. 1, according to the embodiments of the present disclosure, one end of the voltage divider 220 is connected to the selector 210 to form a series relationship with the selector 210 to form an oscillator 102 having a test path. The voltage divider 220 is used to divide a voltage for the selector 210 during a test process. As shown in FIG. 1, the voltage divider 220 needs to be provided in series with the selector 210 to be tested, the voltage divider has a constant resistance to divide the voltage for the selector 210. That is, a voltage of a power supply 101 is applied to the selector 210 and the voltage divider 220. When a fixed voltage applied by the power supply 101 is V_{G}, a voltage of the selector 210 is Vₓ, a voltage on the voltage divider 220 is V_{f}, and the three satisfies:

V_{G}=Vₓ+V_{f}

wherein Vₓ≥Vth, and Vth is a threshold voltage of the selector 210.

When a power supply voltage Vₓ applied to the selector 210 of the oscillator 102 by the power supply 101 or is greater than or equal to the threshold voltage Vₜₕ of the selector 210 to be tested, the selector 210 starts to operate, a resistance value of the selector 210 decreases, and a current flowing through the selector 210 increases from an initial value to a current limit, which corresponds to the turning-on of the selector 210. At this time, a resistance value on the voltage divider 220 remains unchanged. Due to a total voltage V_{G} applied by the power supply 101 is fixed, the voltage V_{f} on the voltage divider 220 may increase with an increase of the current in the test path, and accordingly, the voltage Vₓ of the selector 210 may decrease with the increase of the current. When the current of the selector 210 increases to the current limit, the resistance value of the selector 210 increases, and the current flowing through the selector 210 decreases to the initial value. In this way, the voltage V_{f} on the voltage divider 220 may decrease with a decrease of the current in the test path, and accordingly, the voltage Vₓ of the selector 210 may increase with the decrease of the current. That is, a turning-on cycle of the selector 210 is completed once. The initial current value corresponds to a current value corresponding to the fixed voltage value Vₓ before the selector 210 is turned on.

The voltage divider 220 may be a transistor device or a resistance device with a constant resistance value. In addition to dividing the voltage for the test circuit, so that the oscillator may better utilize threshold characteristics of the selector to realize current and/or voltage oscillations, the voltage divider 220 may further facilitate protecting the test circuit and preventing the selector 210 from being damaged by high voltage breakdown. A structure composition of the oscillator 102 is extremely simple. An oscillation effect of the oscillator 102 may be realized by taking advantage of the threshold characteristics of the selector 210 itself and in combination with the voltage divider 220. The oscillation effect truly reflects the turning-on times of the selector 210, so that a test result is more accurate.

Therefore, periodic voltage and/or current oscillations may be realized by virtue of the threshold characteristics of the selector 210, which shortens a test period and saves a test time. Moreover, the composition of the device is extremely simple.

According to the embodiments of the present disclosure, the other end of the voltage divider 220 is grounded to realize the test path of the device.

According to the embodiments of the present disclosure, the resistance value R_{f} of the voltage divider 220 satisfies:

R_{x_min}≤R_{f}≤R_{x_max}

wherein R_{x_min} is a resistance value when a turn-on voltage of the selector 210 is greater than the threshold voltage of the selector 210, and R_{x_Max} is a resistance value when the turn-on voltage of the selector 210 is less than the threshold voltage of the selector 210. When the voltage divider 220 is the transistor device, by providing a gate voltage, the resistance value R_{f} of the transistor device may be between the resistance R_{x_min} before the turning-on of the selector 210 and the resistance value R_{x_max} after the turning-on of the selector 210. Therefore, cycles of the turning-on times of the selector 210 may be ensured, and a breakdown of the selector may be prevented, so that the test process may be carried out smoothly.

According to the embodiments of the present disclosure, as shown in FIG. 1, the device further includes: a power supply 101 connected to the oscillator 102 to supply power to the oscillator 102 at a constant voltage. The power supply 101 may be a power supply element providing a fixed voltage value. A minimum power supply voltage V_{G} should be equal to the threshold voltage Vₜₕ of the selector 210 to be detected. Specifically, the power supply voltage V_{G} of the power supply 101 satisfies:

V_{G}≥Vₜₕ

wherein 0V<V_{G}≤3V.

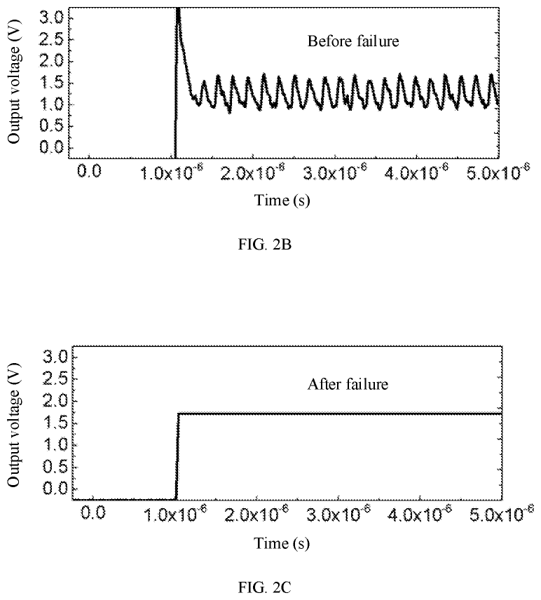

FIG. 2A is a schematic diagram of a voltage-current relationship of a selector according to the embodiments of the present disclosure.

As shown in FIG. 2A, when the power supply voltage V_{G} applied to the selector 210 of the oscillator 102 by the power supply 101 is greater than or equal to the threshold voltage Vₜₕ of the selector 210 to be tested, the selector 210 starts to operate, the resistance value of the selector 210 decreases, and the current flowing through the selector 210 increases from the initial value to the current limit. The current increase of the selector 210 is not a slow change. At this time, the threshold voltage Vₜₕ is the turning-on voltage corresponding to the turning-on of the selector 210. When the current of the selector 210 increases to the current limit, the resistance value of the selector 210 increases, and the current flowing through the selector 210 decreases to the initial value, and the current decrease is also not a slow change. In this way, the turning-on of the selector 210 is completed once. The initial current value corresponds to the current value corresponding to the fixed voltage V_{G} before the selector 210 is turned on.

FIG. 2B is a schematic diagram of a voltage-time relationship before a selector fails according to the embodiments of the present disclosure. FIG. 2C is a schematic diagram of a voltage-time relationship after a selector fails according to the embodiments of the present disclosure.

As shown in FIG. 2B, by virtue of the above-mentioned selector 210 device with threshold switching characteristics, when a fixed voltage is applied to the selector 210, the turning-on of the selector 210 is circulated, the number of the circulated turning-on of the selector 210 corresponds to the number of reciprocating oscillations of the oscillator 102. As shown in FIG. 2C, the selector 210 is applied with a fixed voltage until the turning-on of the selector 210 fails. After the failure of the selector 210, the resistance value of the selector 210 is fixed, and the current flowing through the selector 210 tends to be fixed.

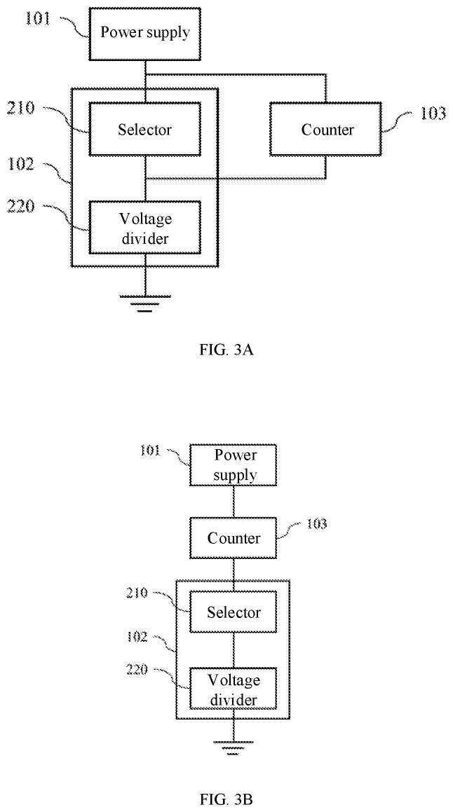

FIG. 3A is a schematic diagram of a logical composition of a counter of a device for testing fatigue characteristics of a selector according to the embodiments of the present disclosure. FIG. 3B is a schematic diagram of a logical composition of another counter of a device for testing fatigue characteristics of a selector according to the embodiments of the present disclosure.

As shown in FIG. 3A, according to the embodiments of the present disclosure, the counter 103 is connected in parallel with the selector 210 to detect a voltage change of the selector 210.

Due to the threshold characteristics of the selector 210 itself, in a case that the voltage value applied to the oscillator 102 by the power supply 101 is fixed: when the voltage Vₓ of the selector 210 is greater than or equal to the threshold voltage Vₜₕ of the selector, an internal current of the oscillator 102 used to compose the test circuit may increase, when flowing through the selector 210 and the voltage divider 220 connected in series, due to a reduction of the resistance value of the selector 210, so that the voltage V_{f} on the voltage divider 220 may increase due to the increase of the current, and the voltage Vₓ of the selector 210 may decrease due to the increase of the voltage V_{f} on the voltage divider 220, and the turning-on of the selector 210 is completed; when the voltage Vₓ of the selector 210 is less than the threshold voltage Vₜₕ of the selector, the resistance value of the selector 210 increases, so that a path current in the oscillator 102 decreases, the voltage V_{f} on the voltage divider 220 decreases due to the decrease of the current, and the voltage Vₓ of the selector 210 increases due to the decrease of the voltage V_{f} on the voltage divider 220, the turning-off of the selector 210 is completed, and the selector 210 is restored to an initial state.

So far, the selector 210 completes one time of a turning-on and turning-off process. The turning-on and turning-off process is repeated until the selector fails. In this process, the counter 103 is connected in parallel with the selector to monitor the number of changes in the voltage value of the selector 210 in real time, so that the turning-on times of the selector 210 before the failure may be obtained, that is, the fatigue characteristics of the selector 210 may be reflected by the voltage change.

As shown in FIG. 3B, according to the embodiments of the present disclosure, the counter 103 is connected in series with the selector 210 to detect a current change of the selector 210.

Due to the threshold characteristics of the selector 210 itself, in a case that the voltage value applied to the oscillator 102 by the power supply 101 is fixed: when the voltage Vₓ of the selector 210 is greater than or equal to the threshold voltage Vₜₕ of the selector, an internal current of the oscillator 102 used to compose the test circuit may increase, when flowing through the selector 210 and the voltage divider 220 connected in series, due to a reduction of the resistance value of the selector 210, and may reach a maximum current limit to complete the turning-on of the selector 210; when the voltage Vₓ of the selector 210 is less than the threshold voltage Vₜₕ of the selector, the resistance value of the selector 210 increases, so that a path current in the oscillator 102 decreases, the turning-off of the selector 210 is completed, and the selector 210 is restored to an initial state.

So far, the selector 210 completes one time of a turning-on and turning-off process. The turning-on and turning-off process is repeated until the selector fails. In this process, the counter 103 is connected in series with the selector to monitor the number of changes in the current value of the selector 210 in real time, so that the turning-on times of the selector 210 before the failure may be obtained, that is, the fatigue characteristics of the selector 210 may be reflected by the current change.

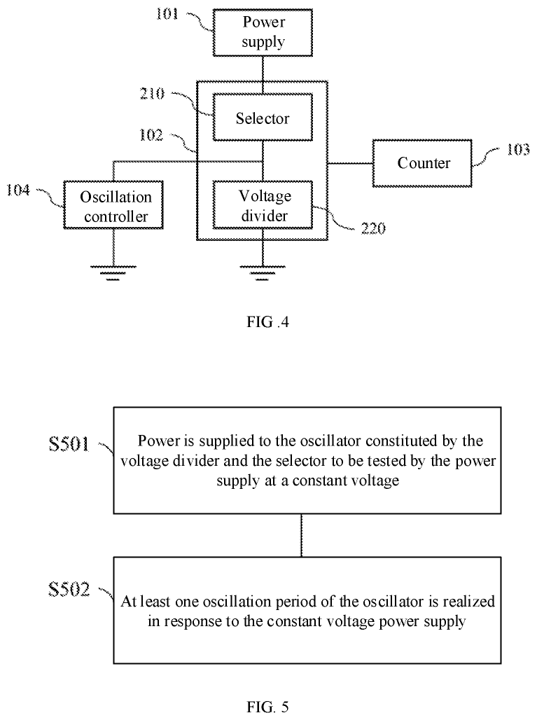

FIG. 4 is a schematic diagram of a logical composition of an oscillation controller of a device for testing fatigue characteristics of a selector according to the embodiments of the present disclosure.

As shown in FIG. 4, according to the embodiments of the present disclosure, the device further includes: an oscillation controller 104, one end of the oscillation controller 104 is connected to the oscillator 102 to control a length of an oscillation period of the oscillator 102, and the other end of the oscillation controller 104 is grounded to realize a control path connected in parallel with the oscillator 102.

The oscillation controller 104 may be a capacitance, and in particular, the capacitance may have an RC charge-discharge circuit. When the power supply 101 applies a fixed voltage V_{G} to the oscillator 102 and the oscillation controller 104, a slow rise or fall of the voltage Vₓ applied to the selector 210 may be realized by virtue of the RC charge-discharge circuit. Therefore, the oscillation controller 104 may realize an adjustment and control of action duration of the voltage Vₓ of the selector 210, such as an adjustment and control of action duration of the turning-on and turning-off process of the selector 210, which finally reflects the adjustment and control of the duration of repeating the cycle of turning-on and turning-off of the selector 210. The oscillation period is the duration of one time of the turning-on and turning-off process during the test of the selector 210.

Therefore, through the oscillation controller 104, the device of the present disclosure may also realize the adjustment and control of the length of the test period during the test of the selector 210 so as to adapt to test requirements of various selectors. Meanwhile, the test period of the selector may also be shortened accordingly, so that the test process is more controllable.

It should be noted that the oscillation controller 104 may be connected in parallel with the voltage divider of the oscillator 102 and may form a corresponding control path.

So far, the device for testing fatigue characteristics of a selector according to the embodiments of the present disclosure has been described in detail in combination with FIG. 1 to FIG. 4.

FIG. 5 is a flow diagram of a method for testing fatigue characteristics of a selector according to the embodiments of the present disclosure.

As shown in FIG. 1 to FIG. 5, another aspect of the present disclosure discloses a method for testing fatigue characteristics of a selector which is applied to the device for testing fatigue characteristics of a selector as describe above. The method includes the following steps.

In S501, the power supply 101 is controlled to supply power to the oscillator 102 at a constant voltage to realize voltage and/or current changes of the selector 210 during a test process.

In S502, at least one oscillation period of the oscillator 102 is realized in response to the constant voltage power supply.

The device includes the voltage divider 220 connected with the selector 210 to be tested so as to form the oscillator 102.

It can be seen that, the device of the present disclosure selects the selector 210 to be tested as the composition of the oscillator 102, so that the structure of the device of the present disclosure is more simplified, and complex circuit components such as the pulse generator and the judgment circuit are omitted. In addition, periodic voltage and/or current oscillations may be realized based on the characteristics of the selector 210, which shortens the test cycle and saves the test time. Moreover, the device is extremely simple in composition and low in cost, thus having an important commercial application value.

As shown in FIG. 1 to FIG. 5, according to the embodiments of the present disclosure, the at least one oscillation period of the oscillator 102 being realized in response to the constant voltage power supply includes:

in response to the constant voltage power supply, the turn-on voltage of the selector 210 is controlled to be greater than the threshold voltage of the selector 210, so that the current in the test path of the device decreases; and

in response to the decrease of the current in the test path, the turn-on voltage of the selector 210 is controlled to be less than the threshold voltage of the selector 210, so that at least one oscillation period of the oscillator 102 is completed.

The technical content of the above-mentioned method may be obtained by those skilled in the art based on the foregoing description of the device, and will not be repeated here.

The present disclosure discloses a device and a method for testing fatigue characteristics of a selector. The device includes a voltage divider and a counter, the voltage divider is connected to a selector to be tested and is used to divide a voltage for the selector to be tested during a test. The counter is connected to the selector to be tested and is used to detect voltage and/or current changes of the selector to be tested. The selector to be tested is selected as a composition of an oscillator, so that a structure of the device of the present disclosure is more simplified, and complex circuit compositions such as a pulse generator, a judgment circuit and the like are omitted. In addition, periodic voltage and/or current oscillations are realized based on characteristics of the selector, which shortens a test period and saves a test time. Moreover, the device is extremely simple in composition and low in cost, thus having an important commercial application value.

So far, the method for testing fatigue characteristics of a selector according to the embodiments of the present disclosure has been described in detail in combination with FIG. 1 to FIG. 5.

The specific embodiments described above further explain the objectives, the technical solutions and the advantages of the present disclosure in detail. It should be understood that the content described above are merely specific embodiments of the present disclosure, and should not be used to limit the present disclosure. Any modifications, equivalent replacements, improvements and the like made within the spirit and principle of the present disclosure should be included in the protection scope of the present disclosure.

1. A device for testing fatigue characteristics of a selector, comprising:
a voltage divider connected to a selector to be tested, wherein the voltage divider is configured to divide a voltage for the selector to be tested during a test process; and
a counter connected to the selector to be tested, wherein the counter is configured to detect voltage and/or current changes of the selector to be tested.

2. The device according to claim 1, wherein,
the voltage divider and the selector to be tested are connected in series to form an oscillator, and the oscillator is configured to reflect voltage and/or current changes of the selector to be tested during the test process.

3. The device according to claim 2, further comprising an oscillation controller, wherein,
one end of the oscillation controller is connected to the oscillator to control a length of an oscillation period of the oscillator; and
the other end of the oscillation controller is grounded to realize a control path connected in parallel with the oscillator.

4. The device according to claim 1, wherein,
the other end of the voltage divider is grounded to realize a test path of the device.

5. The device according to claim 1, wherein,
the voltage divider has a resistance value R_{f} satisfying:
R_{x_min}≤R_{f}≤R_{x_max}
wherein R_{x_min} is a resistance value when a turn-on voltage of the selector to be tested is greater than a threshold voltage of the selector to be tested, and R_{x_max} is a resistance value when the turn-on voltage of the selector to be tested is less than the threshold voltage of the selector to be tested.

6. The device according to claim 2, further comprising:
a power supply connected to the oscillator, wherein the power supply is configured to supply power to the oscillator at a constant voltage.

7. The device according to claim 1, wherein the counter is connected in parallel with the selector to be tested to detect the voltage change of the selector to be tested.

8. The device according to claim 1, wherein the counter is connected in series with the selector to be tested to detect the current change of the selector to be tested.

9. A method for testing fatigue characteristics of a selector, applied to the device according to claim 1, wherein the method comprises:
supplying power to an oscillator formed by the selector to be tested and the voltage divider at a constant voltage though a power supply, so as to realize voltage and/or current changes of the selector to be tested during a test process; and
realizing at least one oscillation period of the oscillator in response to the constant voltage power supply.

10. The method according to claim 9, wherein the realizing at least one oscillation period of the oscillator in response to the constant voltage power supply comprises:
realizing that a turn-on voltage of the selector to be tested being greater than a threshold voltage of the selector to be tested in response to the constant voltage power supply, so that a current in a test path of the device decreases; and
realizing that the turn-on voltage of the selector to be tested being less than the threshold voltage of the selector to be tested in response to the decrease of the current in the test path, so that at least one oscillation period of the oscillator is completed,
wherein the voltage divider is connected in series with the selector to be tested to form the oscillator, and the oscillator is configured to reflect voltage and/or current changes of the selector to be tested during the test process.
